(19) United States
(12) Patent Application Publication
(10) Pub. No.: US 2012/0229906 A1
(43) Pub. Date: Sep. 13, 2012

(54) Anti-Reflection Optical Element and Method for Manufacturing Anti-Reflection Optical Element

(75) Inventors: Masaaki Miyahara, Saitama-shi (JP); Terufusa Kunisada, Saitama-shi (JP); Minoru Shibuya, Saitama-shi (JP)

(73) Assignee: TAMRON CO., LTD., Saitama-shi (JP)

(21) Appl. No.: 13/416,350

(22) Filed: Mar. 9, 2012

(30) Foreign Application Priority Data
Mar. 11, 2011 (JP) 2011-053836

(51) Int. Cl. G02B 5/00; C23C 16/44; B05D 5/06; B82Y 20/00

(52) U.S. Cl. 359/601; 427/162; 977/700; 977/902

(57) ABSTRACT

An object of the present invention is to provide an anti-reflection optical element excellent in durability in the environment high-temperature and high-humidity and scratch resistance while maintaining the anti-reflection performance of a concave-convex nanostructure.

To achieve the object, an anti-reflection optical element 1 comprising a concave-convex nanostructure 20 that reduces reflection of incident light on an optical surface 11 of a base optical element 1 comprising a cover layer 30 made of a light-transmitting material that covers an outer surface of the concave-convex nanostructure 20, wherein a peak of convex portion 21 of the concave-convex nanostructure 20 is covered with the cover layer 30 in the state where a space 40 is provided between the cover layer 30 and concave portions 22 of the concave-convex nanostructure 20 is employed.

### BACKGROUND OF THE INVENTION

1. Field of the Invention

The present invention relates to an anti-reflection optical element comprising an anti-reflection structure on an optical surface of a base optical element, and a method for manufacturing the anti-reflection optical element. More particularly, the invention relates to an anti-reflection optical element comprising a concave-convex nanostructure that reduces reflection of incident light as an anti-reflection structure, and a method for manufacturing the anti-reflection optical element.

2. Background Art

Anti-reflection optical elements comprising an anti-reflection structure has been conventionally used to reduce a loss of transmitted light due to surface reflection on an optical surface of an optical element such as a lens. A concave-convex nanostructure where convex portions are regularly provided at a shorter interval than the wavelength of the incident light is known as one example of the anti-reflection structure (for example, see Japanese Patent Laid-Open Nos. 2005-157119 and 2010-48896). When the concave-convex nanostructure is provided on the optical surface of a base optical element, the optical element can achieve an anti-reflection effect corresponding to a wide wavelength band and a wide incident angle of a light.

However, the surface area of the concave-convex nanostructure is much larger than the surface area of the optical surface of the base optical element. Thus, for example, when the optical element is stored for a long period of time in an environment high-temperature and high-humidity, minute shape in the concave-convex nanostructure may be lost by adsorption of water or the like to the concave-convex nanostructure and anti-reflection performance may be lost.

The concave-convex nanostructure has numerous convex portions that protrude from the optical surface of the base optical element. To reduce reflection, it is required to achieve a gradual distribution of a refractive index in a depth direction of the concave-convex nanostructure. For this reason, the convex portions may have a tapered shape whose peak is thinner than the proximal end. Thus, a problem that the surface of the concave-convex nanostructure might be easily damaged mechanically, i.e. poor in scratch resistance.

Based on the above circumstances, it is an object of the present invention to provide an anti-reflection optical element excellent in durability in the environment high-temperature and high-humidity and scratch resistance while maintaining the anti-reflection performance of a concave-convex nanostructure, and a method for manufacturing the anti-reflection optical element.

### SUMMARY OF THE INVENTION

As a result of intense study, the present inventors have achieved the above object by employing an anti-reflection optical element described below.

An anti-reflection optical element according to the present invention is an anti-reflection optical element comprising a concave-convex nanostructure that reduces reflection of incident light on an optical surface of a base optical element, further comprising a cover layer made of a light-transmitting material that covers an outer surface of the concave-convex nanostructure, wherein a peak of convex portion of the concave-convex nanostructure is covered with the cover layer in the state where a space is provided between the cover layer and a concave portions of the concave-convex nanostructure.

In the anti-reflection optical element according to the present invention, it is preferable that the concave-convex nanostructure is made of a resin material and the adjacent peaks of the convex portions in the concave-convex nanostructure are provided in a pitch width of 200 nm or less.

In the anti-reflection optical element according to the present invention, it is preferable that a refractive index of the cover layer is 1.15 or more and 2.35 or less, and more preferable refractive index is 1.15 or more and 1.50 or less. Here, it is preferable to form the cover layer having a refractive index in the above range by using an inorganic light-transmitting material as the light-transmitting material constituting the cover layer and controlling deposition conditions or the like. To be more specific, the cover layer having a refractive index in the above range can be formed when for example, SiO₂, MgF₂, Al₂O₃, Nb₂O₅, Ta₂O₅, TiO₂, a mixture of La₂O₃ and TiO₂, HfO₂, SnO₂, ZrO₂, a mixture of ZrO₂ and TiO₂, a mixture of Pr₆O₁₁ and TiO₂, a mixture of Al₂O₃ and La₂O₃, and La₂O₃ are used as the inorganic light-transmitting material and the deposition conditions or the like are controlled.

In the anti-reflection optical element according to the present invention, it is preferable that the cover layer is formed as a porous film made of the light-transmitting material including voids by using the light-transmitting material as a raw material for film formation, and has a lower refractive index than a refractive index of the light-transmitting material itself. The cover layer having a lower refractive index than the refractive index of the light-transmitting material itself used as the deposition material, i.e. the refractive index of the light-transmitting material in a bulk state can be obtained by controlling the deposition conditions such that the light-transmitting material including the voids generated during secondary particle growth in a deposition process is deposited by a physical vapor deposition or the like, for example. That is, in the present invention, the refractive index of the cover layer can be made lower than the refractive index of the light-transmitting material constituting the cover layer.

In the anti-reflection optical element according to the present invention, it is preferable that the cover layer has a thickness of between 5 nm and 50 nm inclusive. Here, when the refractive index of the cover layer is 1.15 or more and 2.35 or less, the film thickness is preferably 5 nm or more and 25 nm or less, and more preferably 5 nm or more and 10 nm or less.

In the anti-reflection optical element according to the present invention, it is preferable that the concave-convex nanostructure is provided on an optical thin film composed of a single layer or multilayer at a surface of the base optical element.

In the anti-reflection optical element according to the present invention, it is preferable that the cover layer is formed by depositing the light-transmitting material on the peaks of the convex portions of the concave-convex nanostructure by a physical vapor deposition while rotating a base optical element held by a dome or planetary substrate carrier. Examples of the physical vapor deposition include a vacuum vapor deposition, a magnetron sputtering, and an ion-plating.

An anti-reflection optical element according to the present invention is an anti-reflection optical element comprising a concave-convex nanostructure that reduces reflection of incident light on an optical surface of a base optical element, the concave-convex nanostructure is provided on an optical thin film composed of a single layer or multilayer at a surface of the base optical element, the cover layer made of a light-transmitting material that covers an outer surface of the concave-convex nanostructure is provided, and the peaks of the convex portions of the concave-convex nanostructure are covered with the cover layer in the state where a space is provided between the cover layer and a concave portions of the concave-convex nanostructure.

A method for manufacturing an anti-reflection optical element according to the present invention is a method for manufacturing the above anti-reflection optical element, wherein a cover layer is formed by depositing a light-transmitting material on the peaks of the convex portions of a concave-convex nanostructure by a physical vapor deposition while rotating a base optical element held by a dome or planetary substrate carrier. A wide variety of deposition methods exemplified above and any other methods may be employed as the physical vapor deposition.

According to the anti-reflection optical element according to the present invention, since the cover layer is provided to cover the peaks of the convex portions of the concave-convex nanostructure, the durability in the environment high-temperature and high-humidity of the anti-reflection optical element can be improved by preventing adsorption of water or the like to the surface of the concave-convex nanostructure. Since the peaks of the convex portions of the concave-convex nanostructure are covered with the cover layer, the concave-convex nanostructure can be protected from mechanical attack, and the scratch resistance of the anti-reflection optical element can be improved.

Further according to the anti-reflection optical element according to the present invention, the outer surface of the concave-convex nanostructure is covered with the cover layer made of the light-transmitting material such that the peaks of the convex portions of the concave-convex nanostructure are covered with the cover layer in the state where the space is provided between the cover layer and the concave portions of the concave-convex nanostructure. In contrast, when the entire surface of the concave-convex nanostructure is covered with the cover layer along the surface shape, i.e. the concave-convex shape thereof without the space between the concave-convex nanostructure and the cover layer, incident light is reflected by the light-transmitting material that covers the surface of the convex portions of the concave-convex nanostructure. Then, anti-reflection function of the concave-convex nanostructure might be lost. However in the present invention, only the peaks of the convex portions of the concave-convex nanostructure are coated with the cover layer and the space is provided between the cover layer and the concave portions. That is, difference in the refractive index between the air as the medium of incident light and the concave-convex nanostructure is made smaller, and the incident light can be prevented from being reflected. As described above, the present invention can provide the anti-reflection optical element excellent in durability in the environment high-temperature and high-humidity and scratch resistance while maintaining the anti-reflection performance of the concave-convex nanostructure.

### BRIEF DESCRIPTION OF THE DRAWINGS

FIG. 1 is a schematic view illustrating the cross section of an anti-reflection optical element according to the present invention;

FIG. 2 is a schematic view for demonstrating the configuration of a cover layer for comparison with the anti-reflection optical element according to the present invention;

FIG. 3 is a view illustrating the configuration of a dome-like spin substrate holder used for forming a cover layer according to the present invention;

FIG. 4 is a view illustrating the configuration of a planet-like spin substrate holder used for forming the cover layer according to the present invention;

FIG. 5 is a graph showing refractive index distributions in a film thickness direction of the anti-reflection optical elements manufactured in Example 1 and Comparative Example 1;

FIG. 6 is a graph showing reflectance of the anti-reflection optical elements manufactured in Example 1 and Comparative Example 1 corresponding to the wavelength of the incident light;

FIG. 7 is a graph showing a refractive index distribution in a film thickness direction of the anti-reflection optical element manufactured in Example 2;

FIG. 8 is a graph showing a refractive index distribution in a film thickness direction of the anti-reflection optical element manufactured in Example 3;

FIG. 9 is a graph showing a refractive index distribution in a film thickness direction of the anti-reflection optical element manufactured in Example 4;

FIG. 10 is a graph showing reflectance of the anti-reflection optical elements manufactured in Examples 2 to 4 corresponding to the wavelength of the incident light;

FIG. 11 is a graph showing a refractive index distribution in a film thickness direction of the anti-reflection optical element manufactured in Example 5;

FIG. 12 is a graph showing a refractive index distribution in a film thickness direction of the anti-reflection optical element manufactured in Example 6;

FIG. 13 is a graph showing reflectance of the anti-reflection optical elements manufactured in Examples 2, 5 and 6 corresponding to the wavelength of the incident light;

FIG. 14 is a graph showing a refractive index distribution in a film thickness direction of the anti-reflection optical element manufactured in Example 7;

FIG. 15 is a graph showing a reflectance of the anti-reflection optical element manufactured in Example 7 corresponding to the wavelength of the incident light;

FIG. 16 is a graph showing a refractive index distribution in a film thickness direction of the anti-reflection optical element manufactured in Example 8;

FIG. 17 is a graph showing a reflectance of the anti-reflection optical element manufactured in Example 8 corresponding to the wavelength of the incident light;

FIG. 18 is a graph showing a refractive index distribution in a film thickness direction of the anti-reflection optical element manufactured in Example 9;

FIG. 19 is a graph showing a refractive index distribution in a film thickness direction of the anti-reflection optical element manufactured in Comparative Example 2;

FIG. 20 is a graph showing reflectance of the anti-reflection optical elements manufactured in Example 9 and Comparative Example 2 corresponding to the wavelength of the incident light; and

FIG. 21 is a graph showing reflectance of the anti-reflection optical elements manufactured in Example 9 and Comparative Example 2 corresponding to the wavelength of the incident light.

10: Base optical element
11: Optical surface
20: Concave-convex nanostructure
21: Convex portion
22: Concave portion
30: Cover layer
40: Space
50: Optical thin film

### DETAILED DESCRIPTION OF THE PREFERRED EMBODIMENTS

In the following, an embodiment of an anti-reflection optical element and a method for manufacturing the anti-reflection optical element according to the present invention will be described with reference to the drawings.

### (Anti-Reflection Optical Element)

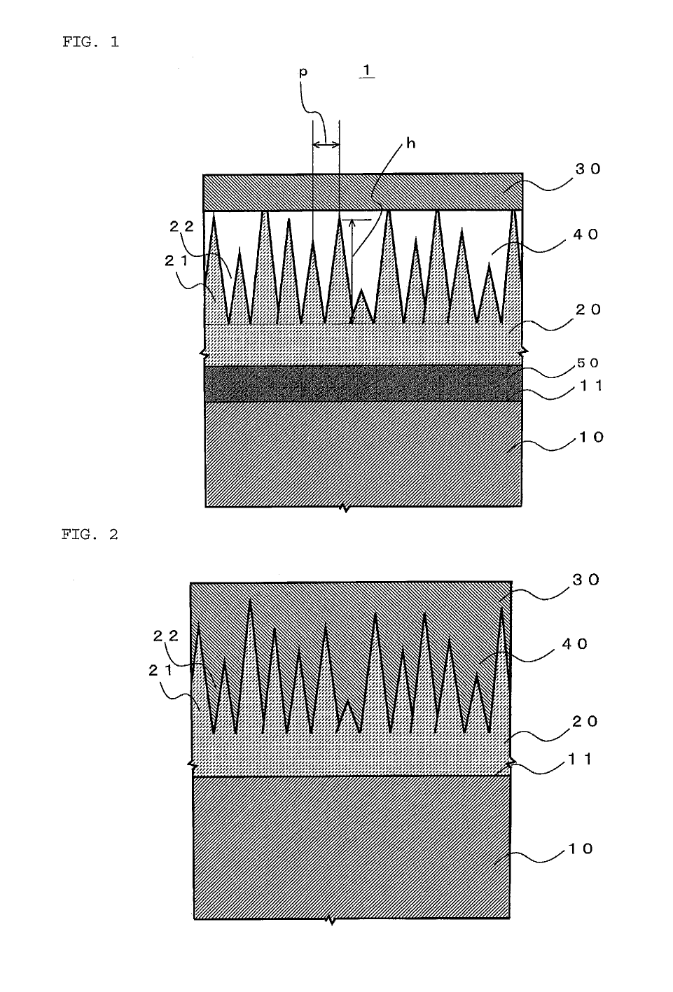

First, the configuration of an anti-reflection optical element 1 according to the present embodiment will be described with reference to FIGS. 1 and 2. FIG. 1 is a schematic view illustrating the configuration of the anti-reflection optical element 1 according to the present embodiment. As shown in FIG. 1, the anti-reflection optical element 1 according to the present embodiment comprises a concave-convex nanostructure 20 that reduces reflection of incident light on an optical surface 11 of a base optical element 10. The outer surface of the concave-convex nanostructure 20 is covered with a cover layer 30 made of a light-transmitting material. In the present invention, the outer surface of the concave-convex nanostructure 20 is covered with the cover layer 30 such that the peaks of the convex portions 21 of the concave-convex nanostructure 20 are covered with the cover layer 30 with a space 40 (an air layer) being provided between the cover layer 30 and concave portions 22 of the concave-convex nanostructure. In the following, each constituent will be described one by one.

Base optical element 10: With regard to the base optical element 10 to be provided with the concave-convex nanostructure 20 on the optical surface 11, lenses of a digital still camera, an analog still camera, various microscopes or the like can be exemplified. However, the base optical element 10 may not be limited to the lens, and may be applied to various elements such as an anti-reflection film, a polarization splitting prism, a color separation prism, an infrared cut filter, a density filter, and an integrator or the like. The base optical element 10 may be made of a glass material, or a resin material. The material constituting the base optical element 10 is not limited to a specific material.

Concave-convex nanostructure 20: The concave-convex nanostructure 20 provided on the optical surface 11 of the base optical element 10 is preferably made of a resin material. By using the resin material, a concave-convex structure can be accurately formed with a fine pitch width. As a result, anti-reflection structures of the same quality can be mass-produced. An additive (inorganic oxide or the like) for providing various functions may be appropriately added to the resin material if required.

As shown in FIG. 1, the concave-convex nanostructure 20 comprises a plurality of (numerous) convex portions 21 that protrude from the optical surface 11. The convex portions 21 of the concave-convex nanostructure 20 are regularly provided adjacent to each other. Each of the convex portions 21 has a tapered shape such as a cone, a pyramid, and a polygonal pyramid (including a shape whose peak is partially cut away), and a gradual refractive index distribution is achieved in a depth direction of the concave-convex nanostructure 20.

A pitch width p of the adjacent peaks of the convex portions 21 is preferable to be 200 nm or less in the concave-convex nanostructure 20. Here, the pitch width p indicates a distance between the peak positions of adjacent convex portions 21, for example. The pitch width p can be measured by electronic microscope observation.

As the pitch width p of the peaks of the convex portions 21 is 200 nm or less, the outer surface of the concave-convex nanostructure 20 can be covered by forming the cover layer 30 by a physical vapor deposition such as a vacuum vapor deposition described below in the state where the space 40 is provided between the cover layer 30 and the concave portions 22. In other words, if the pitch width p of the adjacent peaks of the convex portions 21 is 200 nm or less when the cover layer 30 is formed by the vacuum vapor deposition or the like, the outer surface of the concave-convex nanostructure 20 can be covered with the cover layer 30 without filling the concave portions 22 with a cover layer constituting material (the light-transmitting material) by employing a specific method for deposition according to the present invention.

In contrast, when the pitch width p exceeds 200 nm, the concave portions 22 of the concave-convex nanostructure 20 are tend to be filled with the cover layer constituting material when the cover layer 30 is formed by the vacuum vapor deposition or the like. When the concave portions 22 of the concave-convex nanostructure 20 are filled with the cover layer constituting material, the gradual refractive index distribution to be formed in the depth direction of the concave-convex nanostructure 20 cannot be achieved and it makes the anti-reflection performance of the concave-convex nanostructure 20 poor. Also when the pitch width p exceeds 200 nm, light scattering may be caused to result a loss of transmitted light or generation of stray light, and further the function of the cover layer 30 as a protective film may also be made poor.

A height h of the convex portions 21 is preferably be 50 nm or more and 250 nm or less. Here, “the height h of the convex portions 21” indicates a distance from a proximal end portion to a peak portion of the convex portion 21 as shown in FIG. 1. The height h of the convex portions 21 can be investigated by electron microscope observation. When the height h of the convex portions 21 is 50 nm or more and 250 nm or less, the gradual refractive index distribution can be formed in the depth direction of the concave-convex nanostructure 20 by forming the convex portions 21 in a tapered shape. As a result, reflection of incident light in a visible light range can be effectively prevented. In contrast, it is not preferable that the height h of the convex portions 21 is out of the above range since an anti-reflection effect against visible light may be made poor.

However, as long as the concave-convex nanostructure 20 can achieve the required anti-reflection effect, the height h of the convex portions 21 is not limited in practice in the present invention. The above range is just a preferable range. Thus, even if the height exceeds the above range, there is no problem as long as the concave-convex nanostructure 20 achieves the required anti-reflection effect.

Cover layer 30: Next, the cover layer 30 will be described. As has been already described, in the anti-reflection optical element 1 according to the present embodiment, the cover layer 30 covers the outer surface of the concave-convex nanostructure 20 such that the peaks of the convex portions 21 of the concave-convex nanostructure 20 are covered with the cover layer 30 in the state where the space 40 is provided between the cover layer 30 and the concave portions 22 of the concave-convex nanostructure. Here, the cover layer 30 is the layer which performs as a protective film of the concave-convex nanostructure 20 and an optical thin film.

In practice, by providing the cover layer 30, the mechanical damage on the concave-convex nanostructure 20 can be prevented to improve the scratch resistance of the anti-reflection optical element 1. That is, the cover layer 30 functions as the protective film.

Also, the cover layer 30 is the optical thin film which functions as an anti-reflection layer in cooperation with the concave-convex nanostructure 20. As described above, the concave-convex nanostructure 20 has the gradual refractive index distribution in the depth direction. It is preferable to make film thickness of the cover layer 30 set to an appropriate range according to the refractive index since a refractive index distribution closer to an ideal state can be formed in the depth direction of the anti-reflection layer. Moreover, when the cover layer 30 having a refractive index in a range described below is provided on the outer surface of the concave-convex nanostructure 20, the refractive index distribution in the depth direction of the anti-reflection layer may be made closer to an ideal state. That is, the anti-reflection layer as a laminated body comprising a refractive index gradient layer having the concave-convex nanostructure 20 and the air layer, and the cover layer 30 having a predetermined refractive index are provided on the optical surface 11 of the base optical element 10. As a result, the refractive index distribution closer to an ideal state is formed in the depth direction of the anti-reflection layer as compared to a case in which the anti-reflection layer comprises only the concave-convex nanostructure 20. As a result, the anti-reflection effect of the anti-reflection optical element 1 can be improved.

The refractive index of the cover layer 30 is preferable to be 1.15 or more and 2.35 or less. If the refractive index is intended to be less than 1.15 and exceeds 2.35, it is difficult to form the cover layer 30 having desired refractive index. From the above viewpoint, a lower refractive index is more preferable for the light-transmitting material constituting the cover layer 30 and a refractive index of 1.5 or less is more preferable.

The cover layer 30 is preferably formed as a porous film made of the light-transmitting material including voids generated during deposition. When the cover layer 30 is formed as the porous film, the refractive index of the cover layer can be made lower than the refractive index of the light-transmitting material itself. That is, the refractive index of the cover layer 30 can be made lower than the refractive index of the light-transmitting material used as a deposition material, i.e. the refractive index of the light-transmitting material in a bulk state. For example, when the light-transmitting material is deposited by the physical vapor deposition such as the vacuum vapor deposition, the light-transmitting material including the voids generated during secondary particle growth is deposited. The porous film made of the light-transmitting material can be thereby obtained. The voids of about several nm (for example, 5 nm or less) in size are dispersed in the cover layer 30.

The volume ratio of the voids which occupy the cover layer 30 is preferable to be less than 70%. When the volume ratio of the voids is 70% or more, the durability of the cover layer 30 is made poor and the function as the protective film may also be made poor. From the above viewpoint, the volume ratio of the voids which occupy the cover layer 30 is more preferable to be less than 50%, and yet more preferably less than 30%. In contrast, the minimum value of volume ratio of the voids which occupy the cover layer 30 can be set to an appropriate value based on the refractive index of the light-transmitting material used as the deposition material and the refractive index required for the cover layer 30, i.e. the minimum value is not limited in practice.

Next, with regard to the light-transmitting material, it is preferable to use inorganic light-transmitting material. As described above, the cover layer 30 is provided to prevent the mechanical damage on the concave-convex nanostructure 20 and improve the scratch resistance of the anti-reflection optical element 1. Since the inorganic light-transmitting material generally has higher mechanical strength than a resin light-transmitting material, the inorganic light-transmitting material is preferable to be used as the material constituting the cover layer 30.

Further, as the cover layer 30 performs function as the optical thin film which adjusts the refractive index distribution in the depth direction of the anti-reflection layer to be close to an ideal distribution as described above, the cover layer 30 is provided to improve the anti-reflection performance of the anti-reflection optical element 1. As a refractive index of the inorganic light-transmitting material distributes in a wider range, and it enables a higher degree of freedom in selection of the material in optical design than the resin light-transmitting material, the inorganic light-transmitting material is preferable to be used as the material constituting the cover layer 30. By depositing the inorganic light-transmitting material including the voids by the physical vapor deposition described later, the refractive index of the cover layer 30 can be made lower than the refractive index of the material itself. Thus, the degree of freedom in selection of the material in optical design can be further increased.

With regard to the inorganic light-transmitting material having a refractive index of 2.35 or less, Al₂O₃, Nb₂O₅, Ta₂O₅, TiO₂, a mixture of La₂O₃ and TiO₂, HfO₂, SnO₂, ZrO₂, a mixture of ZrO₂ and TiO₂, a mixture of Pr₆O₁₁ and TiO₂, a mixture of Al₂O₃ and La₂O₃, and La₂O₃ can be exemplified. As the inorganic light-transmitting material having a refractive index of 1.5 or less, SiO₂ and MgF₂ can be exemplified.

A film thickness of the cover layer 30 is preferable to be 5 nm or more and 50 nm or less. The film thickness of the cover layer 30 less than 5 nm is not preferable since the cover layer may be too thin to fully perform the protective film function so as to prevent the mechanical damage on the concave-convex nanostructure 20. Next, the film thickness of the cover layer 30 exceeding 50 nm is not preferable since incident light may be reflected by the cover layer 30 or scattered depending on the refractive index of the light-transmitting material constituting the cover layer 30, thereby causing a loss of transmitting light. In view of the anti-reflection performance, the film thickness of the cover layer 30 is preferably set to an optimum value based on the refractive index of the cover layer 30. In practice, when the light-transmitting material having a refractive index of 1.5 to 2.35 is used, the thickness of the cover layer 30 is preferably 25 nm or less, and more preferably 10 nm or less. It is because an optimum film thickness in view of the anti-reflection performance based on the refractive index of the cover layer 30 exists in the above range. In contrast, when the refractive index is less than 1.5, an optimum film thickness of the cover layer 30 in view of the anti-reflection performance is 5 nm or more and 50 nm or less.

Optical thin film 50: It is preferable that the optical thin film 50 (an anti-reflection thin-film layer) composed of a single layer or a plurality of layers is provided on the optical surface 11 of the base optical element 10 and the concave-convex nanostructure 20 is provided on the optical thin film 50. As a result, the optical thin film 50 functions as the anti-reflection layer cooperation with the concave-convex nanostructure 20 and the cover layer 30. As described above, the anti-reflection layer provided on the optical surface 11 of the base optical element 10 is provided as a composite layer of the optical thin film 50, the concave-convex nanostructure 20 and the cover layer 30. As a result, the refractive index distribution in the depth direction of the anti-reflection layer can be made yet closer to ideal refractive index distribution in achieving the anti-reflection performance. However, FIG. 1 just shows the position of the optical thin film 50, and does not show the number of layers constituting the optical thin film 50.

Such optical thin film 50 can be obtained by laminating a single layer or a plurality of layers formed by using MgF₂, SiO₂, Al₂O₃, Nb₂O₅, Ta₂O₅, TiO₂, a mixture of La₂O₃ and TiO₂, HfO₂, SnO₂, ZrO₂, a mixture of ZrO₂ and TiO₂, a mixture of Pr₆O₁₁ and TiO₂, a mixture of Al₂O₃ and La₂O₃, and La₂O₃ by various depositions, for example. The material constituting the optical thin film 50 is not limited to the above materials. The thickness or the like of the optical thin film 50 can be set to an appropriate value in achieving the anti-reflection performance.

As described above, the anti-reflection optical element 1 according to the present embodiment comprises the cover layer 30 that covers the peaks of the convex portions 21 of the concave-convex nanostructure 20. Thus, the durability in the environment high-temperature and high-humidity of the anti-reflection optical element 1 can be improved by preventing adsorption of water or the like to the surface of the concave-convex nanostructure 20. Since the peaks of the convex portions 21 of the concave-convex nanostructure 20 are covered with the cover layer 30, the concave-convex nanostructure 20 can be protected from the mechanical attack, and the scratch resistance of the anti-reflection optical element 1 can be improved. Moreover, the cover layer 30 functions as the optical thin film, and can improve the anti-reflection performance of the anti-reflection optical element 1 in cooperation with the concave-convex nanostructure 20.

In the anti-reflection optical element 1 according to the present embodiment, the outer surface of the concave-convex nanostructure 20 is covered with the cover layer 30 made of the light-transmitting material in the state where the space 40 is provided between the cover layer 30 and the concave portions 22 of the concave-convex nanostructure. In contrast, for example, if the cover layer 30 covers the entire surface of the concave-convex nanostructure 20 along the surface shape, i.e. the concave-convex shape thereof without the space 40 between the cover layer 30 and the concave-convex nanostructure 20 as shown in FIG. 2, incident light might be reflected by the light-transmitting material that covers the convex portions 21 of the concave-convex nanostructure 20. Then the anti-reflection function of the concave-convex nanostructure 20 may be lost. However, when the cover layer 30 coats only the peaks of the convex portions 21 of the concave-convex nanostructure 20 and the space 40 is provided between the cover layer 30 and the concave portions 22 as shown in the above embodiment, there is a smaller difference in the refractive index between the concave-convex nanostructure 20 and the air as the medium of incident light transmitted through the cover layer 30, so that the incident light can be prevented from being reflected. As a result, the anti-reflection optical element 1 according to the above embodiment is made excellent in durability in the environment high-temperature and high-humidity and scratch resistance while maintaining the anti-reflection performance of the concave-convex nanostructure 20.

### (Method for Manufacturing the Anti-Reflection Optical Element 1)

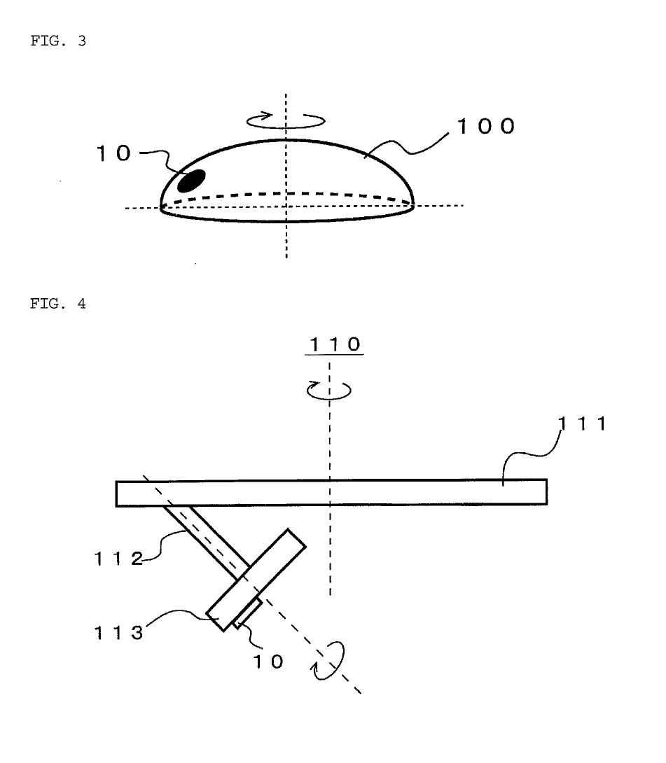

Next, one example of the method for manufacturing the anti-reflection optical element 1 will be described with reference to FIGS. 3 and 4. The method for manufacturing the anti-reflection optical element 1 includes the following steps, for example:
A) a step of forming a concave-convex nanostructure; and
B) a step of forming a cover layer.

In the following, the respective steps will be described.

### A) Step of Forming a Concave-Convex Nanostructure

The step of forming a concave-convex nanostructure is a step of providing the concave-convex nanostructure 20 on the optical surface 11 of the base optical element 10. Various methods may be employed depending on the material constituting the base optical element 10. In the present invention, the step of forming a concave-convex nanostructure is not limited in practice. However, as a method to achieve accurate formation of a finer concave-convex structure, the present embodiment employs a method in which the concave-convex nanostructure 20 is formed in a resin surface (a resin film or the optical surface 11) provided on the optical surface 11 of the base optical element 10 by plasma etching. When the plasma etching is performed as described later, an inorganic oxide film of TiO₂ or the like is preferable to be formed on the resin surface before carrying out the plasma etching.

(1) Case in which the Base Optical Element 10 Made of Glass is Used

When the base optical element 10 is made of glass, the base optical element 10 may be provided with a resin film on the optical surface 11. Examples of a material constituting the resin film include PMMA resin (polymethylmethacrylate resin), ZEONE® resin manufactured by ZEON CORPORATION, Japan, polycarbonate resin, cycloolefin resin, polyethersulfone resin, polyetherimide resin, polyamide resin, PET resin, and CR-39 Resin® (allyl diglycol carbonate) manufactured by PPG Industries, Inc. Preferable thickness of the resin film is about 300 nm to 0.5 mm.

On the base optical element 10 provided with the resin film on the optical surface 11, an inorganic oxide film of TiO₂ or the like is formed by electron-beam vapor deposition by using a commercially-available vacuum vapor deposition apparatus (for example, ARES 1510 (manufactured by Leybold Optics)). In the process, the electron-beam vapor deposition is preferably performed at a deposition rate of 0.01 nm/s to 5 nm/s and a vacuum degree of 1×10⁻⁴ Pa to 5×10⁻² Pa. The inorganic oxide film preferably has a film thickness of about 0.3 nm to 2 nm when measured with a quartz film thickness meter mounted to an electron-beam vapor deposition apparatus. As the inorganic oxide film, a SiO₂ film, an MgF₂ film or the like may be formed by the electron-beam vapor deposition in spite of the TiO₂ film.

After that, the plasma etching is carried out for 60 seconds to 500 seconds at a discharge voltage of 50 V to 150 V, a discharge current of 20 A to 60 A, and a substrate bias of 80 V to 150 V. In the processing, Ar gas is charged at a flow rate of 5 sccm to 20 sccm and O₂ gas is charged at a flow rate of 5 sccm to 50 sccm. Here, “sccm” indicates “standard cc/min, at 1 atm (atmospheric pressure: 1.013 hPa), 0° C.”. The resin film is etched in the above processes, so that the concave-convex nanostructure 20 where the pitch width p of the adjacent peaks of the convex portions 21 is about 50 nm to 200 nm and the height h of the convex portions 21 is about 50 nm to 250 nm is formed. The convex portions 21 have a tapered shape.

(2) Case in which the Base Optical Element 10 Made of Resin is Used

When the concave-convex nanostructure 20 is formed on the optical surface 11 of the base optical element 10 made of resin, the surface shape of the concave-convex nanostructure is first formed in the same procedure described above, and then a mold is prepared by nickel electroforming. In preparation of the mold, the base optical element 10 for preparation of the mold (herein after, referred to as “mold fabricating body”) is prepared first. The mold fabricating body is the same with the base optical element 10 where the concave-convex nanostructure is formed. For example, the mold fabricating body is made of PMMA resin. The concave-convex nanostructure is formed on the optical surface 11 in the same manner described above. The concave-convex nanostructure where the pitch width p of the adjacent peaks of the convex portions 21 is about 50 nm to 200 nm and the height h of the convex portions 21 is about 50 nm to 250 nm is thereby formed. Then, gold is deposited to a thickness of, for example, 1 nm by sputtering along the minute concave-convex shape on the surface of the concave-convex nanostructure 20 of the mold fabricating body where the concave-convex nanostructure is formed. The mold fabricating body on which the gold thin film is formed is used to fabricate the mold by nickel electroforming. By using the mold formed as described above, the concave-convex nanostructure is formed on the optical surface 11 of the base optical element 10 made of the PMMA resin or the like by embossing.

### B) Step of Forming a Cover Layer

In the present invention, any method may be employed in the step of forming a cover layer as long as the cover layer 30 can be formed on the outer surface of the concave-convex nanostructure 20 so as to coat only the peaks of the convex portions 21 in the state where the space 40 is provided between the cover layer 30 and the concave portions 22. However, as a result of intense study, the present inventors have found that the cover layer 30 having the above coating configuration according to the present invention can be easily and accurately formed by employing a method described below. The method will be described below.

In the present invention, the step of forming a cover layer is preferably performed by depositing the light-transmitting material on the peaks of the convex portions 21 of the concave-convex nanostructure 20 by the physical vapor deposition while rotating the base optical element 10 having the concave-convex nanostructure 20 on the optical surface 11 in a dome-like spin or planet-like spin. Here, examples of the physical vapor deposition include the vacuum vapor deposition, a magnetron sputtering, and an ion-plating.

With regard to the cover layer constituting material that constitutes the cover layer 30, the light-transmitting material having a refractive index of 1.15 or more and 2.35 or less is used as described above. Also, the inorganic light-transmitting material is preferably used as described above and the specific light-transmitting materials are also described above. For example, an electron-beam vapor deposition is preferably used as the physical vapor deposition. To carry out the electron-beam vapor deposition, the commercially-available electron-beam vapor deposition apparatus (for example, APS 904 (manufactured by Leybold Optics)) may be used, for example. In the process, the electron-beam vapor deposition is preferably carried out at a deposition rate of 0.1 nm/s to 10 nm/s and a vacuum degree of 1×10⁻⁴ Pa to 5×10⁻² Pa.

A dome-like rotational substrate carrier 100 shown in FIG. 3 is preferably used for holding the base optical element 10 having the concave-convex nanostructure 20 on the optical surface 11. As shown in FIG. 3, the base optical element 10 is fixed to the inside of the dome-like rotational substrate carrier 100 by setting the optical surface 11 having the concave-convex nanostructure 20 as a deposition surface. The vaporized cover layer constituting material is preferably brought into contact with the deposition surface at an angle of 20 to 80 degrees while rotating the dome-like rotational substrate carrier 100 about a rotation shaft (not shown). Alternatively, the base optical element 10 is preferably fixed to the rotational substrate holder for dome-like rotation 100 in a region where a distance from the rotation center position is ½ to 1 when a distance from the rotation center position to the outer rim of the dome-like rotational substrate carrier 100 is 1. The base optical element 10 is more preferably fixed in a region where the distance from the rotation center position is ⅔ to 1. The vaporized cover layer constituting material comes into contact with the surface of the rotating concave-convex nanostructure 20 at an inclined angle, so that the cover layer 30 can be formed on the outer surface of the concave-convex nanostructure 20 such that only the peaks of the convex portions 21 are coated with the cover layer 30 in the state where the space 40 is provided between the cover layer 30 and the concave portions 22 without filling the concave portions 22 with the cover layer constituting material. An inclined direction with respect to the surface of the concave-convex nanostructure 20 is specified as an inclined direction with respect to the optical surface 11 of the base optical element 10 (the same applies to the description below).

According to another preferred aspect, a planet-like rotational substrate holder 110 shown in FIG. 4 may also be used for formation of the cover layer 30. The planet-like rotational substrate holder 110 includes a almost disc-shaped revolution base (a planet base) 111, a support shaft 112 rotatably provided at an outer peripheral portion of the revolution base 111 so as to project toward the deposition side and be inclined from the outer peripheral side to the rotation center side on a rotation surface of the revolution base 111, and a planet rotation base (a planet) 113 on which substrate holding surface is attached perpendicular to the support shaft 112. The shape of the planet rotation base 113 is almost a disc also. When the revolution base 111 revolves, the planet rotation base 113 also rotates on its axis by the rotation of the support shaft 112. The base optical element 10 is fixed on the planet rotation base 113 such that the concave-convex nanostructure 20 is made the deposition surface side. The base optical element 10 comes into contact with the vaporized cover layer constituting material while rotating in a planet-like manner. The cover layer 30 can be thereby formed on the outer surface of the concave-convex nanostructure 20 such that only the peaks of the convex portions 21 are coated with the cover layer 30 in the state where the space 40 is provided between the cover layer 30 and the concave portions 22 without filling the concave portions 22 of the concave-convex nanostructure 20 with the cover layer constituting material. The support shaft 112 is preferable to be provided at an inclined angle of 20 to 70 degrees with respect to the revolution base 111. When the support shaft 112 is provided on the revolution base 111 at an inclined angle in the above range, the cover layer 30 according to the present invention can be formed.

The present embodiment described above is just one aspect of the present invention, and of course can be appropriately arranged without departing from the scope of the present invention. Although the present invention will be described below in more detail based on examples and comparative examples, but the present invention is not limited to the following examples.

### Example 1

In Example 1, the base optical element 10 made of glass was used, and the concave-convex nanostructure 20 made of PMMA resin was formed on the optical surface 11 of the base optical element 10. After that, the outer surface of the concave-convex nanostructure 20 was covered with the cover layer 30 by using SiO₂ as the inorganic light-transmitting material. In practice, the anti-reflection optical element in Example 1 was manufactured as described below.

First, a glass lens made of optical glass (product name: S-LAH66 (nd=1.77)) manufactured by OHARA INC. was employed as the base optical element 10. A PMMA resin film having a film thickness of 0.2 mm was provided on the optical surface 11 of the glass lens. Then, TiO₂ film was deposited on the surface of the PMMA resin film by the electron-beam vapor deposition by using the vacuum vapor deposition apparatus ARES 1510 (Leybold Optics) to 1.25 nm thick when measured with a quartz film thickness meter. In the process, the deposition rate was 0.03 nm/s and the vacuum degree in a chamber was 1×10⁻³ Pa. The plasma etching was then performed for about 200 s (seconds) at a substrate bias of 120 V and a discharge current of 50 A. In the process, an Ar gas and an O₂ gas were charged in the chamber respectively at flow rates of 14 sccm and 30 sccm. In the above processes, the concave-convex nanostructure 20 made of the PMMA resin where the pitch width p of the adjacent peaks of the convex portions 21 was about 50 nm to 150 nm and the height h of the convex portions 21 was about 60 nm to 130 nm was formed. After that, the glass lens was attached to the dome-like rotational substrate holder by setting the optical surface 11 where the concave-convex nanostructure 20 was formed as the deposition surface as shown in FIG. 3. Then SiO₂ was deposited by the electron-beam vapor deposition to 20 nm thick when measured with a quartz film thickness meter. In the process, the attachment position of the glass lens to the dome-like rotational substrate holder was adjusted such that vaporized SiO₂ came into contact with the surface of the concave-convex nanostructure 20 at an angle of 20 to 80 degrees. The anti-reflection optical element in Example 1 was manufactured as described above.

### Example 2

In Example 2, the glass lens made of optical glass (product name: S-LAH55 (nd=1.83)) manufactured by OHARA INC. was used as the base optical element 10. The optical thin film 50 composed of four layers (first to fourth layers) shown in Table 1 was formed on the optical surface 11 of the base optical element 10 in the following procedure. Then the concave-convex nanostructure 20 made of PMMA resin was formed on the optical thin film 50. After that, SiO₂ as the inorganic light-transmitting material was used as the deposition material to cover the outer surface of the concave-convex nanostructure 20 with the cover layer 30 in the following procedure. In practice, the anti-reflection optical element in Example 2 was manufactured as described below.

First, an Al₂O₃ film was formed as the first layer on the glass lens made of S-LAH55 as the base optical element 10 by the vacuum vapor deposition. A ZrO₂+TiO₂ film was formed on the surface of the first layer by the vacuum vapor deposition also. An Al₂O₃ film as the third layer and a ZrO₂+TiO₂ film as the fourth layer were formed in a similar manner to the first layer and the second layer. Then A PMMA film was formed on the surface of the fourth layer by spin coating. Next, the plasma etching was carried out in a similar manner to Example 1 on the optical surface 11 of the glass lens as the base optical element 10 where the optical thin film 50 composed of the first to fourth layers and the PMMA film were formed. In the above processes, the concave-convex nanostructure 20 where the pitch width p of the adjacent peaks of the convex portions 21 was about 50 nm to 150 nm and the height h of the convex portions 21 was about 50 nm to 120 nm was formed.

After that, the glass lens was attached to the planet-like rotational substrate holder by setting the optical surface 11 where the concave-convex nanostructure 20 was formed as the deposition surface as shown in FIG. 4. Then SiO₂ was deposited by the vacuum vapor deposition by using the vacuum vapor deposition apparatus ARES 1510 (Leybold Optics) to 20 nm thick when measured with a quartz film thickness meter. In the process, the attachment position of the glass lens to the planet-like rotational substrate holder was set such that the support shaft was inclined at 50 degrees to the revolution base. The anti-reflection optical element in Example 2 was manufactured as described above.

The film composition and film thickness of the anti-reflection optical element manufactured in Example 2 are as shown in Table 1.

TABLE 1

| | Constituent | Film thickness |
|---|---|---|
| | material | (nm) |
| Sixth layer | SiO₂ | 20 |
| (cover layer) | | |
| Fifth layer | PMMA + Air | 99 |
| (gradual refractive index | | |
| layer) | | |
| Fourth layer | ZrO₂ + TiO₂ | 20.3 |
| Third layer | Al₂O₃ | 39.4 |
| Second layer | ZrO₂ + TiO₂ | 31.5 |
| First layer | Al₂O₃ | 10 |
| Substrate (optical element | S-LAH55 | |
| main body) | | |

### Example 3

In Example 3, the anti-reflection optical element was manufactured in a similar manner to the anti-reflection optical element manufactured in Example 2 except that the film thickness of each layer of the optical thin film 50 provided between the optical surface 11 of the base optical element 10 and the concave-convex nanostructure 20 was set as shown in Table 2, and TiO₂ was used as the inorganic light-transmitting material constituting the cover layer 30, and the film thickness of the cover layer 30 was set to 5 nm.

TABLE 2

| | Constituent | Film thickness |
|---|---|---|
| | material | (nm) |
| Sixth layer | TiO₂ | 5 |
| (cover layer) | | |
| Fifth layer | PMMA + Air | 90.5 |
| (gradual refractive index | | |
| layer) | | |
| Fourth layer | ZrO₂ + TiO₂ | 29.3 |
| Third layer | Al₂O₃ | 30.5 |
| Second layer | ZrO₂ + TiO₂ | 40.2 |
| First layer | Al₂O₃ | 10 |
| Substrate (optical element | S-LAH55 | |
| main body) | | |

### Example 4

In Example 4, the anti-reflection optical element was manufactured in a similar manner to the anti-reflection optical element manufactured in Example 2 except that the film thickness of each layer of the optical thin film 50 provided between the optical surface 11 of the base optical element 10 and the concave-convex nanostructure 20 was set as shown in Table 3, and MgF₂ was used as the inorganic light-transmitting material constituting the cover layer 30, and the film thickness of the cover layer 30 was set to 50 nm.

TABLE 3

| | Constituent | Film thickness |
|---|---|---|
| | material | (nm) |
| Sixth layer | MgF₂ | 50 |
| (cover layer) | | |
| Fifth layer | PMMA + Air | 107 |
| (gradual refractive index | | |
| layer) | | |
| Fourth layer | ZrO₂ + TiO₂ | 10.6 |
| Third layer | Al₂O₃ | 46.9 |
| Second layer | ZrO₂ + TiO₂ | 20.5 |
| First layer | Al₂O₃ | 10 |
| Substrate (optical element | S-LAH55 | |
| main body) | | |

### Example 5

In Example 5, the anti-reflection optical element was manufactured in a similar manner to the anti-reflection optical element manufactured in Example 2 except that the film thickness of each layer of the optical thin film 50 provided between the optical surface 11 of the base optical element 10 and the concave-convex nanostructure 20 was set as shown in Table 4, and SiO₂ was used as the inorganic light-transmitting material constituting the cover layer 30, and the film thickness of the cover layer 30 was set to 5 nm.

TABLE 4

| | Constituent | Film thickness |
|---|---|---|
| | material | (nm) |
| Sixth layer | SiO₂ | 5 |
| (cover layer) | | |
| Fifth layer | PMMA + Air | 121.1 |
| (gradual refractive index | | |
| layer) | | |
| Fourth layer | ZrO₂ + TiO₂ | 24.4 |
| Third layer | Al₂O₃ | 34.6 |
| Second layer | ZrO₂ + TiO₂ | 34.4 |
| First layer | Al₂O₃ | 10 |
| Substrate (optical element | S-LAH55 | |
| main body) | | |

### Example 6

In Example 6, the anti-reflection optical element was manufactured in a similar manner to the anti-reflection optical element manufactured in Example 2 except that the film thickness of each layer of the optical thin film 50 provided between the optical surface 11 of the base optical element 10 and the concave-convex nanostructure 20 was set as shown in Table 5, and SiO₂ was used as the inorganic light-transmitting material constituting the cover layer 30, and the film thickness of the cover layer 30 was set to 50 nm.

TABLE 5

| | Constituent | Film thickness |
|---|---|---|
| | material | (nm) |
| Sixth layer | SiO₂ | 50 |
| (cover layer) | | |
| Fifth layer | PMMA + Air | 55.2 |
| (gradual refractive index | | |
| layer) | | |
| Fourth layer | ZrO₂ + TiO₂ | 25.7 |
| Third layer | Al₂O₃ | 36.2 |
| Second layer | ZrO₂ + TiO₂ | 36.8 |
| First layer | Al₂O₃ | 10 |
| Substrate (optical element | S-LAH55 | |
| main body) | | |

### Example 7

In Example 7, an optical lens made of ZEONEX® resin manufactured by ZEON CORPORATION, Japan was used as the base optical element 10. The concave-convex nanostructure 20 was formed on the surface of the optical lens. To form the concave-convex nanostructure 20, the plasma etching was performed on the optical surface 11 of the base optical element 10 in a similar manner to

### Example 2

In the above processes, the concave-convex nanostructure 20 where the pitch width p of the adjacent peaks of the convex portions 21 was about 100 nm to 200 nm and the height h of the convex portions 21 was about 150 nm to 250 nm was formed. After that, SiO₂ was deposited by the electron-beam vapor deposition to 10 nm thick when measured with a quartz film thickness meter while rotating the resin lens in a planet-like manner in a similar manner to Example 2. The anti-reflection optical element in Example 7 was manufactured as described above.

### Example 8

In Example 8, an optical lens made of PMMA resin was used as the base optical element 10 made of resin. The concave-convex nanostructure 20 was formed on the surface of the optical lens. To form the concave-convex nanostructure 20, a mold fabricating body the same with the base optical element 10 was prepared first, and then the plasma etching was performed on the optical surface 11 of the mold fabricating body. To be more specific, a SiN film of about 1 nm thick was formed on the surface of the PMMA resin by reactive direct-current sputtering of a Si target in an Ar/N₂ plasma at 300 W by using a magnetron sputtering apparatus. In the process, an Ar gas and an N₂ gas were charged respectively at flow rates of 10 sccm and 15 sccm. Subsequently, the plasma etching was performed for about 200 s (seconds) in an Ar/N₂ plasma at 100 W by a high-frequency discharge of 13.56 MHz. In the process, an Ar gas and an O₂ gas were charged respectively at flow rates of 10 sccm and 20 sccm. The concave-convex nanostructure 20 where the pitch width p of the adjacent peaks of the convex portions 21 was 50 nm to 120 nm and the height h of the convex portions 21 was also 50 nm to 120 nm was formed on the optical surface 11 of the mold fabricating body. Subsequently, 1 nm thick of gold was deposited by the sputtering along the minute concave-convex shape on the surface of the concave-convex nanostructure 20 of the mold fabricating body. The mold was manufactured by nickel electroforming on the fabricating body where the gold thin film was formed. By using the mold formed as described above, the minute concave-convex shape was transcribed on the optical surface 11 of the base optical element 10 by embossing. The concave-convex nanostructure 20 was thereby formed. After that, the base optical element 10 where the concave-convex nanostructure 20 was formed was attached to the rotational substrate holder, and SiO₂ was deposited by sputtering to 12.4 nm thick when measured with a quartz film thickness meter. The anti-reflection optical element in Example 8 was manufactured as described above.

### Example 9

A glass lens made of N-BK7 glass (nd=1.52) manufactured by SCHOTT AG was used as the base optical element 10. The optical thin film 50 composed of three layers (first to third layers) shown in Table 6 was formed in the following procedure. The concave-convex nanostructure 20 made of PMMA resin was then formed on the optical thin film 50. After that, the outer surface of the concave-convex nanostructure 20 was covered with the cover layer 30 in the following procedure in which SiO₂ as the inorganic light-transmitting material was used as the deposition material to cover. In practice, the anti-reflection optical element in Example 9 was manufactured as described below.

First, an Al₂O₃ film was formed as the first layer on the glass lens made of N-BK7 as the base optical element 10 by the vacuum vapor deposition. A ZrO₂+TiO₂ film was formed on the surface of the first layer by the vacuum vapor deposition also. An Al₂O₃ film was further formed as the third layer in a similar manner to the first layer. A PMMA film was then formed on the surface of the third layer by spin coating. The plasma etching was carried out in a similar manner to Example 2 on the optical surface 11 of the glass lens as the base optical element 10 where the optical thin film 50 composed of the first to third layers and the PMMA film were formed. In the above processes, the concave-convex nanostructure 20 where the pitch width p of the adjacent peaks of the convex portions 21 was about 50 nm to 150 nm and the height h of the convex portions 21 was about 100 nm to 180 nm was formed.

After that, SiO₂ was deposited to 9.6 nm thick when measured with a quartz film thickness meter by the vacuum vapor deposition in a similar manner to Example 2 by setting the optical surface 11 where the concave-convex nanostructure 20 was formed as the deposition surface. The anti-reflection optical element in Example 9 was manufactured as described above.

The film composition and film thickness of the anti-reflection optical element manufactured in Example 9 are as shown in Table 6.

TABLE 6

| | Constituent | Film thickness |
|---|---|---|
| | material | (nm) |
| Fifth layer | SiO₂ | 9.6 |
| (cover layer) | | |
| Fourth layer | PMMA + Air | 140.3 |
| (gradual refractive index | | |
| layer) | | |
| Third layer | Al₂O₃ | 99.6 |
| Second layer | ZrO₂ + TiO₂ | 7.0 |
| First layer | Al₂O₃ | 114.1 |
| Substrate (optical element | N-BK7 | |
| main body) | | |

### Comparative Examples

### Comparative Example 1

In Comparative Example 1, the anti-reflection optical element was manufactured in a similar manner to the anti-reflection optical element manufactured in Example 1 except that the cover layer 30 was not formed.

### Comparative Example 2

In Comparative Example 2, the anti-reflection optical element was manufactured in a similar manner to the anti-reflection optical element manufactured in Example 9 except that the cover layer 30 was not formed.

The film composition and film thickness of the anti-reflection optical element manufactured in Comparative Example 2 are as shown in Table 7.

TABLE 7

| | Constituent | Film thickness |
|---|---|---|
| | material | (nm) |
| Fifth Fourth layer | PMMA + Air | 167.9 |
| (gradual refractive index | | |
| layer) | | |
| Third layer | Al₂O₃ | 111.4 |
| Second layer | ZrO₂ + TiO₂ | 7.0 |
| First layer | Al₂O₃ | 118.3 |
| Substrate (optical element | N-BK7 | |
| main body) | | |

### [Evaluation]

### 1. Properties

1) A refractive index distribution in a film thickness direction (a depth direction) and a reflectance, 2) a scratch resistance, and 3) a durability in the environment high-temperature and high-humidity were respectively measured on the anti-reflection optical elements manufactured in the above Examples and Comparative Examples. A specific method will be described below.

### 1) Measurement of a Refractive Index Distribution in a Film Thickness Direction and a Reflectance

The refractive index distribution in the film thickness direction of the concave-convex nanostructure was measured by using a spectroscopic ellipsometer M-2000 manufactured by J. A. Woollam Co., Inc. with respect to the anti-reflection optical elements manufactured in the respective Examples and Comparative Examples. The reflectance of the respective anti-reflection optical elements when light having a wavelength ranging from 420 nm to 680 nm was emitted to the optical surface of the base optical element through the concave-convex nanostructure was also measured. The reflectance was measured by using a spectrophotometer FE-3000 manufactured by Otsuka Electronics Co., Ltd.

### 2) Evaluation of Scratch Resistance

By using the anti-reflection optical elements manufactured in the respective Examples and Comparative Examples, the optical surface comprising the concave-convex nanostructure are rubbed by a methanol impregnated wiper (MX-CLOTH manufactured by CleanEra) (the same applies to the descriptions below), moved back and forth 10 times with 100 g-f load. After that, the surface of the respective anti-reflection optical elements was visually inspected utilizing transmitted and reflected light under a fluorescent lamp whether there is a scratch or not.

### 3) Evaluation of Durability in the Environment High-Temperature and High-Humidity

The anti-reflection optical elements manufactured in the Examples and Comparative Examples were respectively kept for 240 hours in the environment high-temperature and high-humidity of 90% RH at 60° C. In the anti-reflection optical elements, the reflectance of the respective anti-reflection optical elements before and after keeping in the high-temperature and high-humidity environment was measured, and a change in the reflectance was evaluated.

### 2. Evaluation Results

Then, Evaluation results of the properties above 1) to 3) will be described with respect in Example 1 and Comparative Example 1, Example 2, Example 3, Example 4, Example 5, Example 6, Example 7, Example 8, and Example 9 and Comparative Example 2.

### 2-1. Evaluation Results in Example 1 and Comparative Example 1

### 1) Measurement of a Refractive Index Distribution in a Film Thickness Direction and a Reflectance

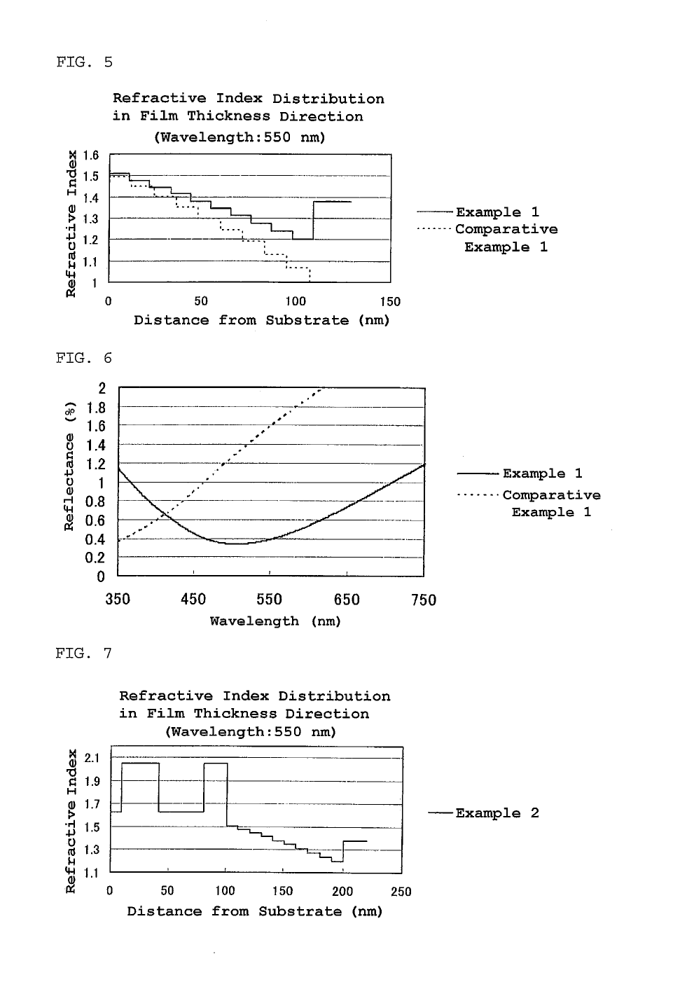

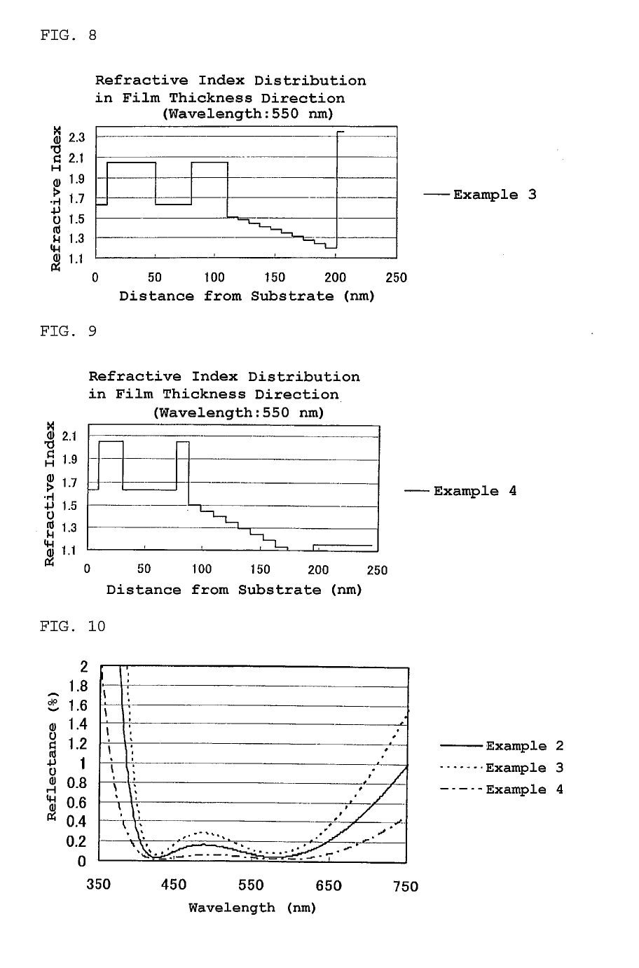

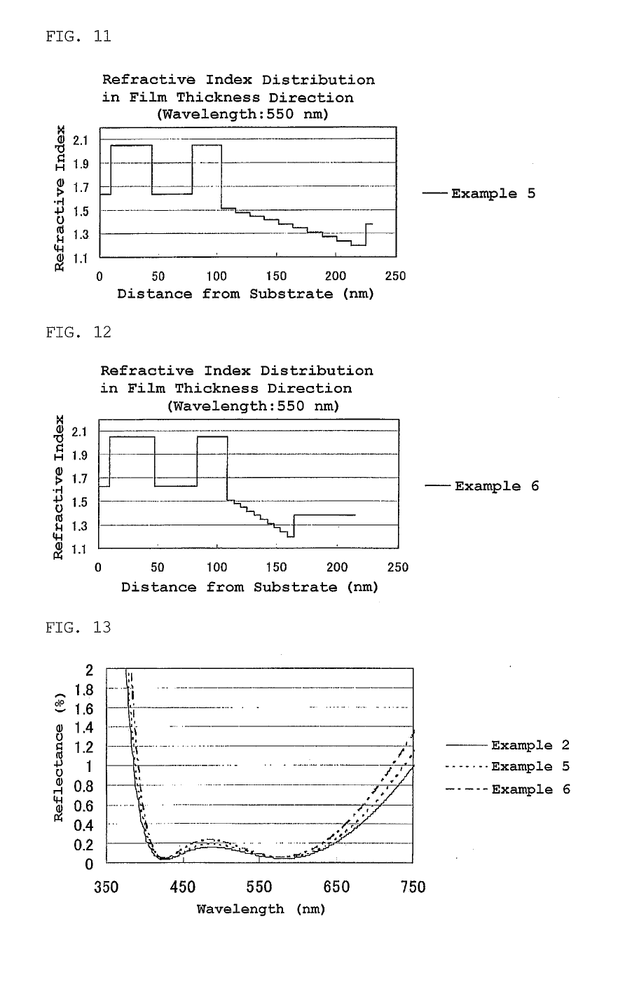

FIG. 5 shows the refractive index distributions in the film thickness direction of the anti-reflection optical elements manufactured in Example 1 and Comparative Example 1. In FIG. 5, the horizontal axis represents the distance from the optical surface of the base optical element, and the vertical axis represents the refractive index (also the same in FIGS. 7, 8, 9, 11, 12, 14, 16, 18 and 19). FIG. 6 shows the reflectances corresponding to the wavelength of the incident light entered to the anti-reflection optical elements. In FIG. 6, the horizontal axis represents the wavelength of the incident light entered to the concave-convex nanostructure, and the vertical axis represents the reflectance of the incident light (also the same in FIGS. 6, 10, 13, 15, 17, 20 and 21).

As shown in FIG. 5, the refractive index distributions of the respective anti-reflection optical elements are almost similar to each other. So, it is proved that the refractive index distribution in the film thickness direction can be maintained when the space between the cover layer 30 and the concave portions 22 of the concave-convex nanostructure 20 is proved even whether the outer surface of the concave-convex nanostructure 20 is covered with the cover layer 30 or not. Next, the refractive index of the cover layer 30 formed on the top surface was 1.38, and is lower than 1.46 which is the refractive index of SiO₂ in a bulk state. The average reflectance of the anti-reflection optical element in Example 1 among the incident light wavelength range of 420 nm to 680 nm was 0.500. In contrast, the average reflectance of the anti-reflection optical element in Comparative Example 1 among the incident light wavelength range described above was 1.55%. That is, it has been confirmed that the gradual refractive index distribution formed in the depth direction of the concave-convex nanostructure 20 can be maintained and the anti-reflection performance of the concave-convex nanostructure 20 can be maintained when the outer surface of the concave-convex nanostructure 20 is covered with the cover layer 30 in the state where the space 40 is provided between the concave portions 22 of the concave-convex nanostructure 20 and the cover layer 30.

### 2) Evaluation Result of Scratch Resistance

No scratch was observed on the surface of the anti-reflection optical element in Example 1 after rubbing the optical surface 11 with the wiper. In contrast, a scratch was observed on the surface of the anti-reflection optical element in Comparative Example 1. That is, it has been confirmed that the cover layer 30 provided on the anti-reflection optical element having the concave-convex nanostructure 20 can improve the scratch resistance.

### 3) Evaluation Result of Durability in the Environment High-Temperature and High-Humidity

No increase in the reflectance was observed in the anti-reflection optical element in Example 1 before and after keeping in the environment high-temperature and high-humidity for 240 hours. In contrast, an increase of the reflectance, i.e. a deterioration of the anti-reflection performance was observed after keeping the anti-reflection optical element in the environment high-temperature and high-humidity for 240 hours in the anti-reflection optical element in Comparative Example 1.

### 2-2. Evaluation Results in Examples 2 to 6

### 1) Measurement of a Refractive Index Distribution in a Film Thickness Direction and a Reflectance

FIGS. 7, 8, 9, 11 and 12 are graphs respectively showing the refractive index distributions in the film thickness direction of the anti-reflection optical elements manufactured in Examples 2 to 6. FIGS. 10 and 13 respectively show the reflectances of the anti-reflection optical elements corresponding to the wavelength of the incident light.

As shown in FIGS. 10 and 13, all the anti-reflection optical elements in Examples 2 to 6 had a reflectance of 1% or less among the incident light wavelength range of 420 nm to 680 nm. Further, the average reflectances of the anti-reflection optical elements in Examples 2 to 6 among the incident light wavelength range described above were 0.12%, 0.21%, 0.05%, 0.14%, and 0.17%, respectively as shown in FIGS. 10 and 13. That is, it has been confirmed that the anti-reflection optical element exhibits anti-reflection performance when the refractive index of the cover layer 30 is 1.15 or more and 2.35 or less and the film thickness is 5 to 50 nm. Since the average reflectance of the anti-reflection optical element in Example 2 among the incident light wavelength range described above was lower than those in Examples 5 and 6, it was confirmed that the anti-reflection optical element exhibits more excellent anti-reflection performance by providing the cover layer 30 with an appropriate film thickness, i.e. the cover layer 30 can improve the optical property (the anti-reflection performance).

### 2) Evaluation Result of Scratch Resistance

No scratch was observed on the surfaces of the anti-reflection optical elements in Examples 2 to 6 after rubbing the optical surface 11 with the wiper. That is, it has been confirmed that the anti-reflection optical element comprising the concave-convex nanostructure 20 provided with the cover layer 30 is excellent in scratch resistance.

### 3) Evaluation Result of Durability in the Environment High-Temperature and High-Humidity

No increase in the reflectance was observed in the anti-reflection optical elements in Examples 2 to 6 before and after keeping in the environment high-temperature and high-humidity for 240 hours.

### 2-3. Example 7

### 1) Measurement of a Refractive Index Distribution in a Film Thickness Direction and a Reflectance

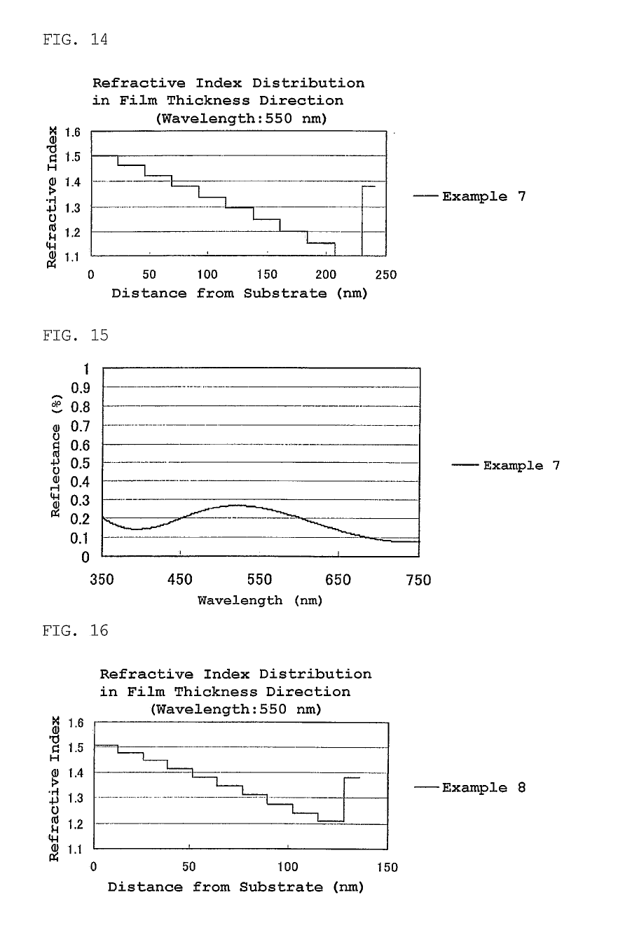

FIG. 14 is a graph showing the refractive index distribution in the film thickness direction of the anti-reflection optical element manufactured in Example 7. FIG. 15 shows the reflectance corresponding to the wavelength of the incident light entered to the anti-reflection optical element. The average reflectance of the anti-reflection optical element in Example 7 among the incident light wavelength range of 420 nm to 680 nm was 0.21%.

### 2) Evaluation Result of Scratch Resistance

No scratch was observed on the surface of the anti-reflection optical element in Example 7 after rubbing the optical surface 11 with the wiper.

### 3) Evaluation Result of Durability in the Environment High-Temperature and High-Humidity

No increase in the reflectance was observed in the anti-reflection optical element in Example 7 before and after keeping in the environment high-temperature and high-humidity for 240 hours.

### 2-4. Example 8

### 1) Measurement of a Refractive Index Distribution in a Film Thickness Direction and a Reflectance

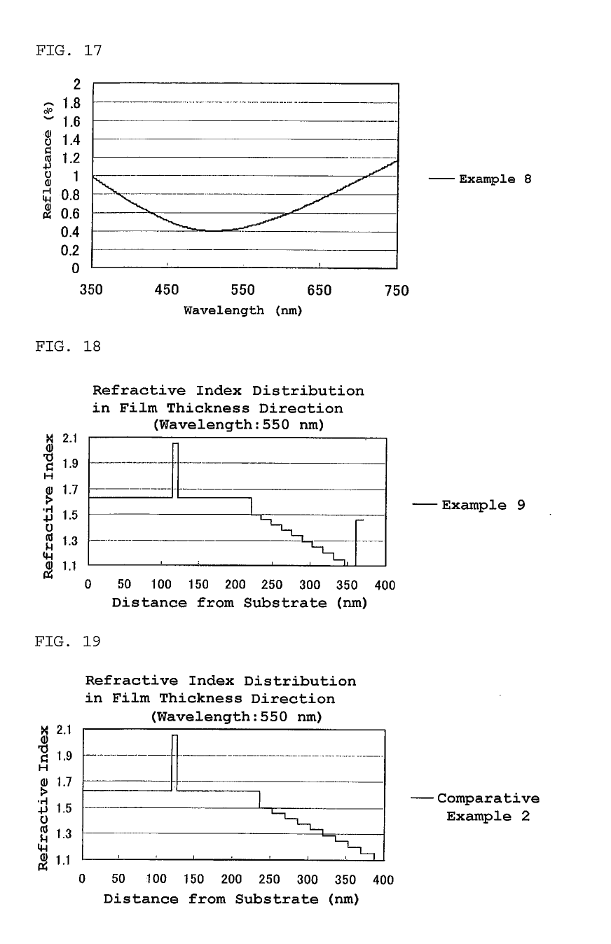

FIG. 16 is a graph showing the refractive index distribution in the film thickness direction of the anti-reflection optical element manufactured in Example 8. FIG. 17 shows the reflectance corresponding to the wavelength of the incident light entered to the anti-reflection optical element. The average reflectance of the anti-reflection optical element in Example 8 among the incident light wavelength range of 420 nm to 680 nm was 0.54%.

### 2) Evaluation Result of Scratch Resistance

No scratch was observed on the surface of the anti-reflection optical element in Example 8 after rubbing the optical surface 11 with the wiper.

### 3) Evaluation Result of Durability in the Environment High-Temperature and High-Humidity

No increase in the reflectance was observed in the anti-reflection optical element in Example 8 before and after keeping in the high-temperature and high-humidity environment for 240 hours.

### 2-5. Evaluation Results in Example 9 and Comparative Example 2

### 1) Measurement of a Refractive Index Distribution in a Film Thickness Direction and a Reflectance

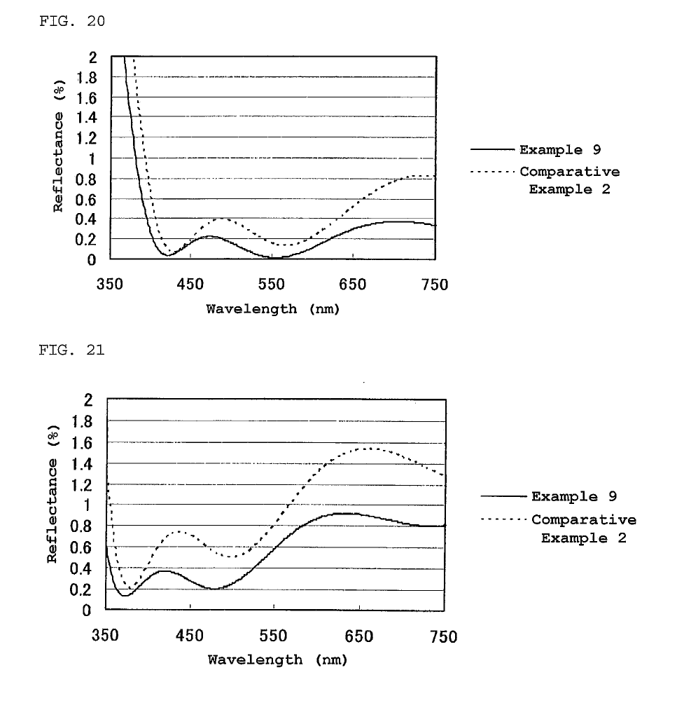

FIGS. 18 and 19 are graphs respectively showing the refractive index distributions in the film thickness direction of the anti-reflection optical elements manufactured in Example 9 and Comparative Example 2. FIG. 20 shows the reflectances corresponding to the wavelength of the incident light of the respective anti-reflection optical elements at an incident angle of 0°. FIG. 21 shows the reflectances corresponding to the wavelength of the incident light of the respective anti-reflection optical elements at an incident angle of 45°.

In Example 9 and Comparative Example 2, the average reflectance among the incident light wavelength range of 420 nm to 680 nm were 0.15% and 0.29% respectively for the incident angle of 0°, and 0.56% and 0.95% respectively for the incident angle of 45°. Since the average reflectance of the anti-reflection optical element in Example 9 among the above incident light wavelength range was lower than that in Comparative Example 2. That is, it was confirmed that the anti-reflection optical element exhibits more excellent anti-reflection performance by providing the cover layer 30 with an appropriate film thickness, i.e. the cover layer 30 can improve the anti-reflection performance.

### 2) Evaluation Result of Scratch Resistance

No scratch was observed on the surface of the anti-reflection optical element in Example 9 after rubbing the optical surface 11 with the wiper. In contrast, a scratch was observed on the surface of the anti-reflection optical element in Comparative Example 2. That is, it has been confirmed that the cover layer 30 formed can improve the scratch resistance of the anti-reflection optical element comprising the concave-convex nanostructure 20.

### 3) Evaluation Result of Durability in the Environment High-Temperature and High-Humidity

No increase in the reflectance was observed in the anti-reflection optical element in Example 9 before and after keeping in the environment high-temperature and high-humidity for 240 hours. In contrast, an increase in the reflectance, i.e. a deterioration of the anti-reflection performance was observed in the anti-reflection optical element in Comparative Example 2 after keeping in the environment high-temperature and high-humidity for 240 hours.

In the anti-reflection optical element according to the present invention, the outer surface of the concave-convex nanostructure is covered with the cover layer that covers the peaks of the convex portions of the concave-convex nanostructure by providing the space in the concave portions of the concave-convex nanostructure. Therefore, the durability in the environment high-temperature and high-humidity and the scratch resistance are improved while maintaining or improving the anti-reflection performance. As a result, the anti-reflection optical element according to the present invention can be preferably used even in an environment high-temperature and high-humidity and it makes maintenance easy. So, the anti-reflection optical element can be preferably applied to various optical elements.

What is claimed is:

1. An anti-reflection optical element comprising a concave-convex nanostructure that reduces reflection of incident light on an optical surface of a base optical element,
comprising a cover layer made of a light-transmitting material that covers an outer surface of the concave-convex nanostructure,
wherein a peak of convex portion of the concave-convex nanostructure is covered with the cover layer in the state where a space is provided between the cover layer and a concave portion of the concave-convex nanostructure.

2. The anti-reflection optical element according to claim 1,
wherein the concave-convex nanostructure is made of a resin material, and
the adjacent peaks of the convex portions in the concave-convex nanostructure are provided in a pitch width of 200 nm or less.

3. The anti-reflection optical element according to claim 1,
wherein a refractive index of the cover layer is 1.15 or more and 2.35 or less.

4. The anti-reflection optical element according to claim 1,
wherein the cover layer is formed as a porous film made of the light-transmitting material including voids by using the light-transmitting material as a raw material for film formation, and has a lower refractive index than a refractive index of the light-transmitting material itself.

5. The anti-reflection optical element according to claim 1,
wherein the cover layer has a thickness of between 5 nm and 50 nm inclusive.

6. The anti-reflection optical element according to claim 1,
wherein the concave-convex nanostructure is provided on an optical thin film composed of a single layer or multilayer at a surface of a base optical element.

7. The anti-reflection optical element according to claim 1,
wherein the cover layer is formed by depositing the light-transmitting material on the peaks of the convex portions of the concave-convex nanostructure by a physical vapor deposition while rotating the base optical element held by a dome or planetary substrate carrier.

8. An anti-reflection optical element comprising a concave-convex nanostructure that reduces reflection of incident light on an optical surface of a base optical element,
wherein the concave-convex nanostructure is provided on an optical thin film composed of a single layer or multilayer at a surface of the base optical element,
a cover layer made of a light-transmitting material that covers an outer surface of the concave-convex nanostructure is provided, and
the peaks of the convex portions of the concave-convex nanostructure are covered with the cover layer in the state where a space is provided between the cover layer and a concave portion of the concave-convex nanostructure.

9. A method for manufacturing an anti-reflection optical element according to claim 1,
wherein the cover layer is formed by depositing the light-transmitting material on the peaks of the convex portions of the concave-convex nanostructure by a physical vapor deposition while rotating the base optical element held by a dome or planetary substrate carrier.
